(19) United States
(12) Patent Application Publication
(10) Pub. No.: US 2016/0315024 A1
(43) Pub. Date: Oct. 27, 2016

(54) MECHANICAL HANDLING SUPPORT FOR THIN CORES USING PHOTO-PATTERNABLE MATERIAL

(71) Applicant: QUALCOMM Incorporated, San Diego, CA (US)

(72) Inventors: Kwan-yu LAI, Campbell, CA (US); Ravindra Vaman SHENOY, Dublin, CA (US); Urmi RAY, San Diego, CA (US)

(21) Appl. No.: 14/691,946

(22) Filed: Apr. 21, 2015

(51) Int. Cl. H01L 23/15; H01L 21/48; H01L 23/498

(52) U.S. Cl. CPC H01L 23/15; H01L 23/49827; H01L 23/49822; H01L 21/4803; H01L 21/486

(57) ABSTRACT

An integrated circuit package includes a core such as a thin glass core with through-core vias. A photo-patternable material is disposed directly on surfaces of the core and in the through-core vias and is selectively patterned to expose at least an exposed portion of the surface of the core and the through-core vias. A metal layer, such as copper, is disposed in the exposed portion of the core and in the through-core vias. A mechanical handler frame may be used to clamp together the various layers including the core and the photo-patternable material. The photo-patternable material that remains after patterning is permanent, and prevents the mechanical handler frame from directly contacting the core. Thus the photo-patternable material provides mechanical support to the core and protects the core from the mechanical handler.

### FIELD OF DISCLOSURE

Disclosed aspects relate to improving support and protection for cores such as glass cores used in integrated circuit packages. In an exemplary aspect, a photo-patternable material is disposed directly on the core to provide support and prevent direct contact of the core from a mechanical handler.

### BACKGROUND

In integrated circuit packaging substrate and interposer fabrication, individual integrated circuits sometimes start from large panels. The panels can have dimensions upwards of 500 mm×500 mm. These large panels are susceptible to warping and bending during the fabrication process. To keep the panels flat during fabrication mechanical handlers, such as window frames, may be used to clamp together the various layers in the panels. As the thickness of the substrate layers in the panels get smaller, e.g., below 200 μm, the handler frames start to become insufficient for the substrate to survive through various process steps. Also, when the substrate is a stiff core, e.g., glass, the mechanical handling frame can scratch the glass core, which makes the glass core weaker and more prone to breaking.

Instead of clamping the mechanical handler frames directly onto the glass core, conventional techniques involve laminating a soft build-up film layer onto the glass core, which forms a permanent layer. The build-up film layer creates a buffering layer that reinforces the thin glass core, provides support for the thin glass core, and prevents direct mechanical contact by mechanical handlers clamping the glass core. However, the additional layers involved in the build-up film increase the total height of the glass core, which adds to stress and warpage of the glass core. Fine line and space patterning is also difficult on the laminated surface of the build-up film due to the roughness of the laminated surface. Moreover forming metal lines, such as copper traces directly on the glass surface is not possible due to the build-up film, which increases electrical losses. Yet another disadvantage of using the build-up films is due to the need for a two-step via-in-via formation process for forming vias because through-glass vias (TGVs) through the glass core will need to be drilled first, these TGVs filled with the build-up film, an inner via created within the build-up film, and then metal connections formed in the inner via.

Accordingly, there is a need for avoiding the aforementioned drawbacks of the conventional approaches for handling glass cores.

### SUMMARY

Exemplary systems and methods relate to an integrated circuit package comprising a core such as a thin glass core with through-core vias. A photo-patternable material is disposed directly on surfaces of the core and in the through-core vias and is selectively patterned to expose at least an exposed portion of the surface of the core and the through-core vias. A metal layer, such as copper, is disposed in the exposed portion of the core and in the through-core vias. A mechanical handler frame may be used to clamp together the various layers including the core and the photo-patternable material. The photo-patternable material that remains after patterning is permanent, and prevents the mechanical handler frame from directly contacting the core. Thus the photo-patternable material provides mechanical support to the core and protects the core from the mechanical handler.

Accordingly, an exemplary aspect relates to an integrated circuit package comprising a core. The core comprises a surface on at least a first side. A photo-patternable material is disposed on the core except on at least an exposed portion of the surface of the core on the first side, and a metal is disposed on the exposed portion.

Another exemplary aspect relates to a method for fabricating an integrated circuit package, the method comprising disposing a photo-patternable material on a surface of at least a first side of a core, patterning the photo-patternable material to expose at least an exposed portion of the surface of at least the first side of the core, and disposing a metal on the exposed portion.

Yet another exemplary aspect relates to an integrated circuit package comprising a core comprising a surface on at least a first side. Photo-patternable means for improving mechanical handling of the core are disposed on the core except on at least an exposed portion of the surface of the core on the first side, and means for making interconnections are disposed on the exposed portion.

### BRIEF DESCRIPTION OF THE DRAWINGS

FIG. 1 is a top view of an integrated circuit package according to implementations of the technology described herein.

FIG. 2 is a side view of the integrated circuit package depicted in FIG. 1 according to alternative implementations of the technology described herein.

FIG. 3 is a more detailed top view of the integrated circuit package depicted in FIG. 1 according to implementations of the technology described herein.

FIG. 4 is a more detailed top view of the integrated circuit package depicted in FIG. 3 according to implementations of the technology described herein.

FIG. 5 is a more detailed top view of the integrated circuit package depicted in FIG. 4 according to implementations of the technology described herein.

FIG. 6 is a side view of an integrated circuit package during fabrication according to implementations of the technology described herein.

FIG. 7 is a side view of an integrated circuit package during fabrication according to implementations of the technology described herein.

FIG. 8 is a side view of an integrated circuit package according to alternative implementations of the technology described herein.

FIG. 9 is a side view of the integrated circuit package depicted in FIG. 8 according to implementations of the technology described herein.

FIG. 10 is a side view of the integrated circuit package according to an implementation of the technology described herein.

FIG. 11 is a flowchart of a method of fabricating an integrated circuit package according to an implementation of the technology described herein.

FIG. 12 is a block diagram showing an exemplary wireless communication system in which an integrated circuit package according to exemplary aspects described herein may be employed.

### DETAILED DESCRIPTION

Aspects of the invention are disclosed in the following description and related drawings directed to specific aspects of the invention. Alternate aspects may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any aspect described herein as “exemplary” is not necessarily to be construed as preferred or advantageous over other aspects. Likewise, the term “aspects of the invention” does not require that all aspects of the invention include the discussed feature, advantage or mode of operation.

The terminology used herein is for the purpose of describing particular aspects only and is not intended to be limiting of aspects of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the aspects described herein, the corresponding form of any such aspects may be described herein as, for example, “logic configured to” perform the described action.

The technology described herein includes improved handling of thin substrate cores such as thin glass cores. For example, glass cores may be a part of a large panel used in forming an integrated circuit package. The panel can include glass cores for multiple dies. Instead using of a build-up film as a material to provide mechanical support and prevent warpage, in exemplary aspects, a photo-patternable material is used as a handling layer. The photo-patternable material is formed on the glass core and patterned to leave permanent patterns remaining on the glass core to provide mechanical support. Metal layers such as copper layers can be directly formed on exposed portions of the glass core which do not have a permanent photo-patternable material remaining.

An example glass core may have at least one through-core via or through-glass via (TGV). The core includes surfaces on a first or top side and a second or bottom side. The photo-patternable material may be disposed directly on the surfaces of the glass core on at least one side (e.g., the top side and/or the bottom side), which also fills up TGVs (if any) in the glass core. The photo-patternable material is then selectively patterned or removed from at least portions of the surfaces of the glass core on at least one side. Thus, the a photo-patternable material remains disposed on the first side, for example, except on at least an exposed portion of the surface of the core on the first side. A metal layer, such as copper, is disposed on the exposed portions of the surfaces of the glass core, such as the exposed portion on the surface of the core on the first side. Due to the patterning, at least one through-core via is also exposed from the photo-patternable material. The metal layer is also disposed in the exposed through-core via. A mechanical handler frame may be used to clamp together the various layers of the panel, such as the glass core and the remaining photo-patternable material. Since the remaining photo-patternable material is permanent after patterning, it prevents the mechanical handler frame from directly contacting the glass core, thus protecting the glass core from damage.

The package according to implementations of the technology described herein has several advantages. For example, conventionally it may only be possible to perform line spacing in the panel to create individual dies along the order of 10-20 μm on the build-up film because the build-up film is rougher than glass. According to aspects of the technology described herein, fine line spacing of around 1-2 μm on glass cores can be accomplished because the glass core is relatively smooth. Being able to finely dice the panel reduces dicing street interference on the panel.

Also, conventionally when the panel is diced into small pieces, the blade of a cutter used for dicing can gum up, making dicing more difficult. In one or more aspects of the technology described herein, the photo-patternable material does not remain on the panel in the dicing streets. Therefore, there is no photo-patternable material to gum up the cutting blade.

Another advantage is that metal lines, e.g., copper lines, are disposed directly on the surfaces of the glass core instead of on the build-up film as in conventional techniques discussed previously. As previously mentioned, in conventional techniques, the build-up film is formed on the glass core, and then a metal e.g., copper, is formed on the build-up film, which can be problematic because the electrical characteristics of the build-up film are not as good as the electrical characteristics of copper. Therefore, there may be more electrical losses with integrated circuits that have copper formed on the build-up film rather than directly on the surfaces of the glass core. In one aspect, because the glass core surface is smoother than the build-up film surface, the glass core is a very low loss material. Since in exemplary aspects, the copper lines are directly disposed on the glass core, power consumption in the resulting dies is reduced.

Another advantage is that only a single through-glass via (TGV) drilling process is used. Conventionally, TGVs are formed using the two-step process discussed previously. In more detail, in the first step of the two-step process, the TGVs are formed in the glass core. The TGVs are then filled with the build-up film. In the second step, an inner via is formed in the build-up film. That is, the TGVs then have to be drilled a second time to remove the build-up film to expose the TGVs. This two-step drilling adds to processing costs. Moreover, having the inner via requires a larger diameter and pitch of the TGVs.

In one or more implementations of the technology described herein, the glass core has the TGVs from the previous drilling process. The photo-patternable material is deposited directly on the surfaces of the glass core, which also fills up the TGVs. The photo-patternable material is selectively patterned to expose portions of the surfaces of the glass core as well as to expose the TGVs. The metal layer is disposed in the exposed TGVs and on the exposed portions of the surfaces of the glass core. Thus, the second step of removing the build-up film to expose the TGVs is eliminated because the patterning step exposes the portions of the surface of the glass core as well as the TGVs. Accordingly, there is no inner via formed by the build-up film to be drilled. Eliminating the inner TGVs also may reduce the diameter and the pitch requirements of the TGVs in exemplary aspects.

Another advantage is reduced stress on the glass core. Stress causes warpage and makes the glass core prone to breakage. When the build-up film is deposited directly on the glass core as a separate layer, the build-up film tends to pull on top and bottom sides of the glass core, causing a tensile stress. At some point, the tensile stress will cause the glass core to break. The weakest points in the glass core tend to be the edges.

In one or more implementations, stress is reduced because the photo-patternable material prevents the build-up film from contacting the edges of the glass core. Also, there is less area of the glass core for the build-up film to pull on. Tensile stress also may be reduced by using a photo-patternable material that has a high elongation and a low Young's modulus. One suitable elongation may be twenty to forty percent. One suitable Young's modulus may be 0.5-2 GPa. Of course other elongations and another Young's modulus may be suitable depending on the particular application. In one or more implementations, the photo-patternable material may be selectively patterned so that it forms a stress buffer at the high stress points, such as the edges of individual dies and solder joints.

Reducing tensile stress on the glass core also allows for a larger body size and improved die reliability. For example, conventionally, the panels have four layers of build-up film on the core material, two layers on a top side of the core material, and two layers on a bottom side of the core material. There may be two layers of solder resist, one layer of solder resist on top of the top-most build-up film layer and one layer of solder resist on the bottom-most build-up film layer. This arrangement adds to the total height of the integrated circuit (IC), adds stress to the glass core.

In one or more implementations, a single layer of build-up film may be deposited on the top side of the core material and a single layer of build-up film on the bottom side of the core material. This allows the panel to be thinner overall.

While in exemplary aspects, the core has been described as a glass core, it will be understood that the core may be formed of any other suitable material such as silicon on which the photo-patternable material and metal lines may be deposited. Correspondingly, the through-core vias may be through-glass vias, through-silicon vias, or any means for connecting the first side and a second side of the core, depending on the material of the core. Further, while several example materials for forming the photo-patternable material are provided, it will be recognized that the photo-patternable material may be any photo-patternable means for improving mechanical handling of the core, disposed on the core except on at least an exposed portion of the surface of the core on at least one side, such as the first side. Similarly, metal, such as copper or any means for making interconnections may be disposed on the exposed portion.

Correspondingly, the through-core vias may be any means for connecting the first side and a second side of the core, which are exposed from the photo-patternable material.

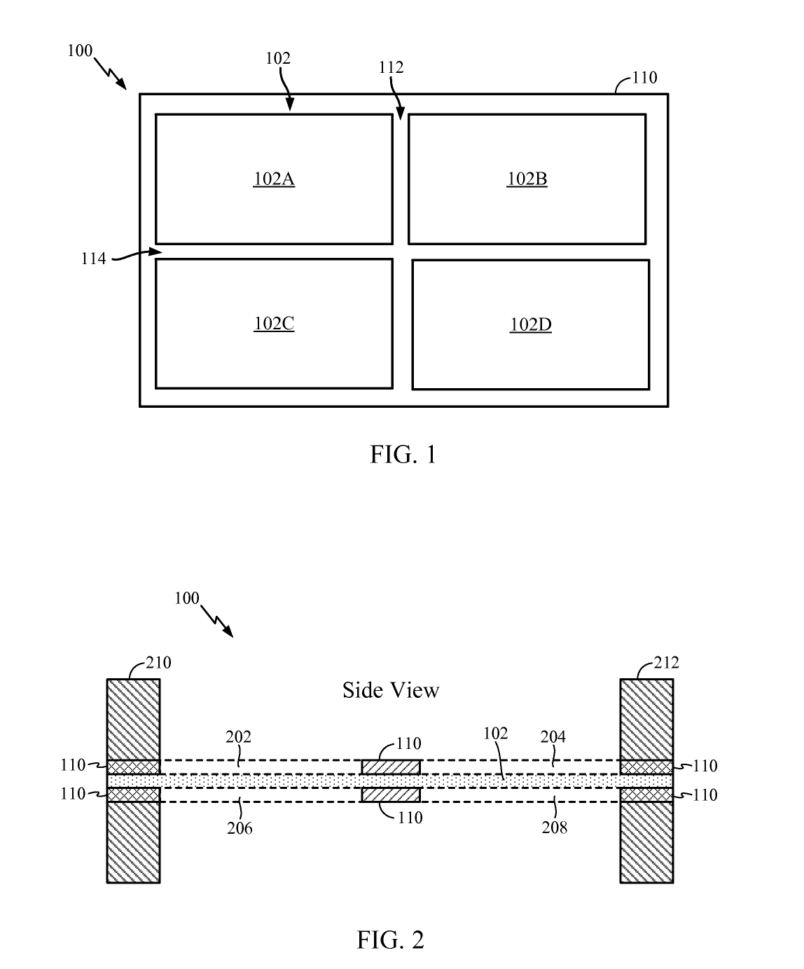

FIG. 1 is a top view of a panel of an integrated circuit package 100 according to implementations of the technology described herein. The illustrated integrated circuit package 100 includes a core 102 that comprises a portion 102A, a portion 102B, a portion 102C, and a portion 102D. Each portion 102A, 102B, 102C, and 102D is surrounded by a photo-patternable material 110. Dicing streets 112 and 114 are patterned into the photo-patternable material 110. Dies, for example, composed of the above portions may be diced from the panel of the integrated circuit package 100 along dicing streets 112 and 114.

In one or more implementations, the panel of the integrated circuit package 100 may be approximately 500-600 mm long on a side. The core 102 may be used in integrated circuit package substrates, interposers, or the like.

In one or more implementations, a ball grid array (BGA) (not shown) may be disposed on a printed circuit board (PCB) formed using dies from the panel of the integrated circuit package 100, for example. The core 102 may form part of an interposer (not shown) or integrated circuit packaging substrate that is disposed on the BGA. A logic integrated circuit (not shown) may be disposed on the interposer. This arrangement may form an integrated circuit package.

In one or more implementations, the core 102 is glass, silicon, or other suitable material onto which the photo-patternable material 110 is disposed. In one or more implementations, the photo-patternable material 110 may be a dielectric or an organic polymer that is sensitive to ultraviolet (UV) light, such as a photoresist. The photo-patternable material 110 may be a soft, compliant layer that has a high elongation, a low Young's modulus, and tensile elasticity. The photo-patternable material 110 may provide mechanical support for the core 102. Suitable material for the photo-patternable material 110 includes a positive photoresist material, a negative photoresist material, photo-patternable photo benzocyclobutene (BCB) material, a polyimide, or other similar polymer that is capable of being patterned.

FIG. 2 is a side view of the integrated circuit package 100 according to implementations of the technology described herein. The integrated circuit package 100 illustrated in FIG. 2 includes the core 102 and the photo-patternable material 110 disposed on surfaces of both sides (i.e., a first or top side and a second or bottom side) of the core 102. Portions of the photo-patternable material 110 may be removed from surfaces of the core 102, for example, by patterning at locations represented by dotted lines 202, 204, 206, and 208.

A clamp 210 is disposed on one end of the integrated circuit package 100 and is in contact with the remaining photo-patternable material 110. A clamp 212 is disposed on another end of the integrated circuit package 100 and is in contact with the remaining photo-patternable material 110.

FIG. 3 is a more detailed top view of the integrated circuit package 100 according to implementations of the technology described herein. The implementation illustrated in FIG. 3 shows the portion 102A of the core 102 comprising a portion 302, a portion 304, a portion 306, and a portion 308. The portion 302 is further shown to comprise a portion 310, a portion 312, a portion 314, and a portion 316.

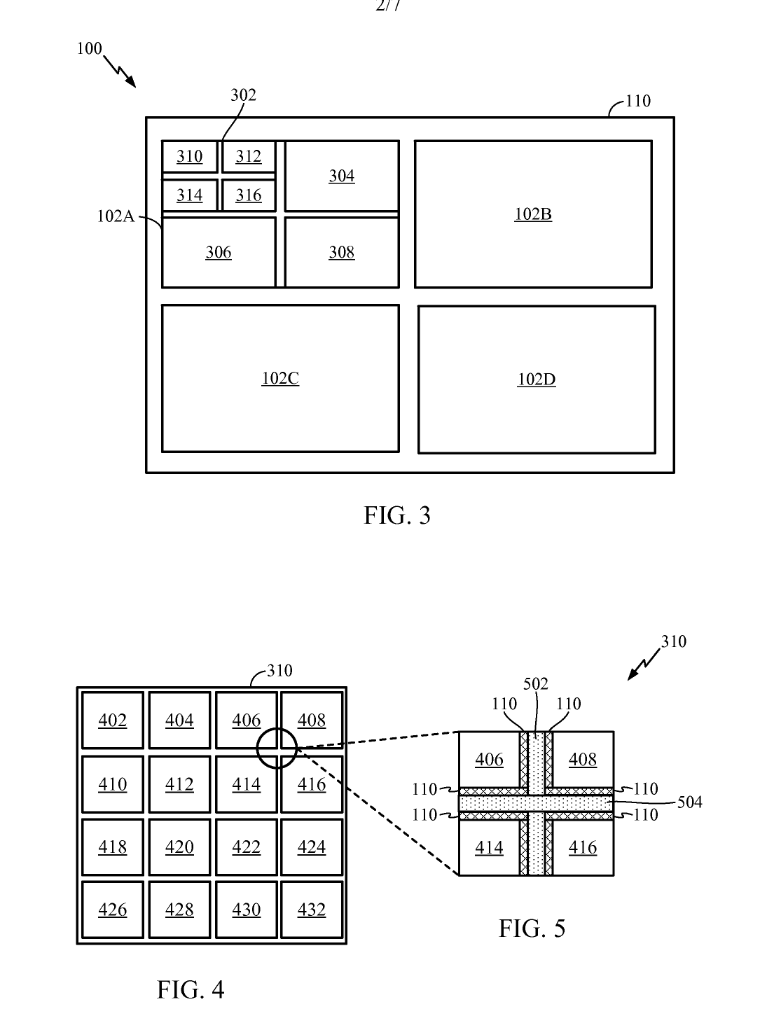

FIG. 4 is a more detailed top view of the portion 310 of a panel, for example, of the integrated circuit package 100 according to implementations of the technology described herein. The portion 310 of the integrated circuit package 100 may be diced into several dies 402, 404, 406, 408, 410, 412, 414, 416, 418, 420, 422, 424, 426, 428, 430, and 432.

FIG. 5 is an exploded top view of the dies 406, 408, 414, and 416 according to implementations of the technology described herein. Each of the dies 406, 408, 414, and 416 includes portions of the core 102 whose surface is exposed (i.e., the portions from which the photo-patternable material 110 has been removed). The exposed core 102 surface may be used for fine line patterning, for additional circuitry, for example. Moreover, as shown in the exploded view in FIG. 5, the photo-patternable material 110 may not be limited to only the outer edges of the panel of the integrated circuit package 100, but may also be patterned to remain at the outer edges of each of the dies 406, 408, 414, and 416, as shown.

The arrangement of the dies 406, 408, 414, and 416 forms a dicing street 502 and a dicing street 504. The dies 406, 408, 414, and 416 may be diced or cut along the dicing streets 502 and 504.

In one or more implementations, the dicing streets 502 and 504 do not have photo-patternable material 110 disposed thereon. The photo-patternable material 110 may be selectively patterned and removed from the dicing streets 502 and 504 prior to dicing.

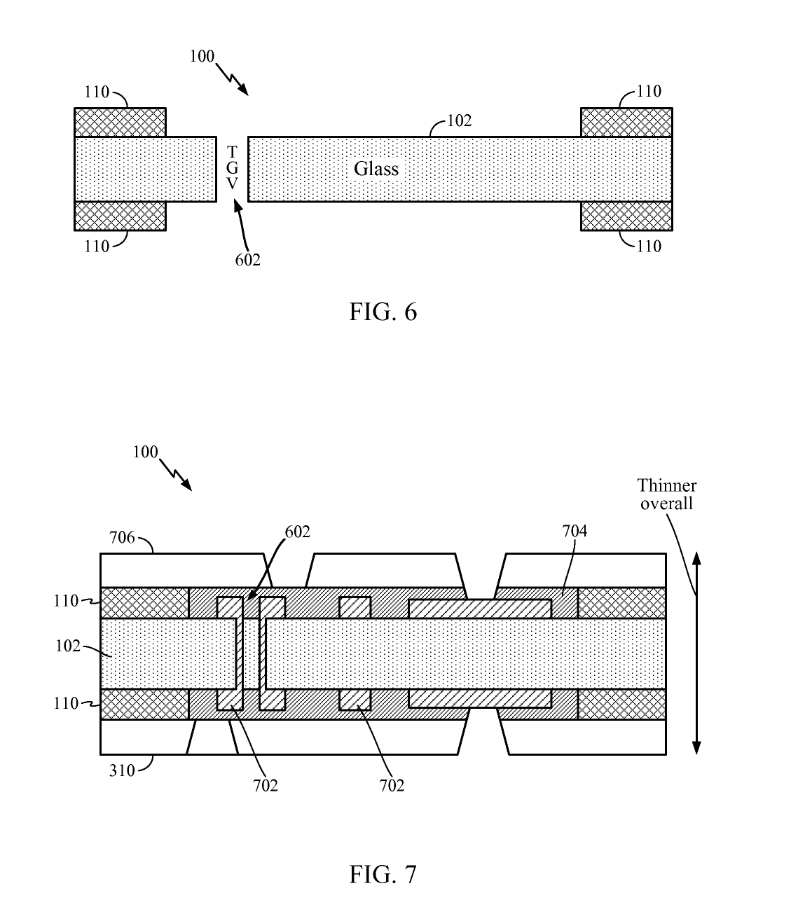

FIG. 6 is a side view of the integrated circuit package 100 during fabrication according to implementations of the technology described herein. The illustrated implementation includes the core 102, the photo-patternable material 110 remaining on portions of the surfaces of the core 102 on at least one side (e.g., the top and/or bottom sides). A through-core via such as a through-glass via (TGV) 602 (where the core 102 is made of glass) is formed in the core 102. The TGV 602 extends between the top and bottom sides of the core 102. In one or more implementations, the photo-patternable material 110 is removed from the TGV 602 during the patterning process used to expose the surfaces on the top and bottom sides of the core 102.

FIG. 7 is a side view of the integrated circuit package 100 according to implementations of the technology described herein. In the implementation illustrated in FIG. 7, the core 102 includes the TGV 602. The photo-patternable material 110 is formed on the core 102 and patterned to expose portions of the surface of the core 102. The photo-patternable material 110 is also patterned to be removed from the TGV 602. A metal 702 is formed directly on the exposed surfaces of the core 102 and within the TGV 602. The metal 702 may be copper or any other suitable metal. Although one through-core via such as TGV 602 is shown, there may be more than one through-core vias similar to TGV 602.

A build-up film 704 is formed on the exposed surface of the core 102, on the metal 702, and in the TGV 602 using known techniques. A solder resist layer 706 is formed on the build-up film 704 and on the patterned photo-patternable material 110.

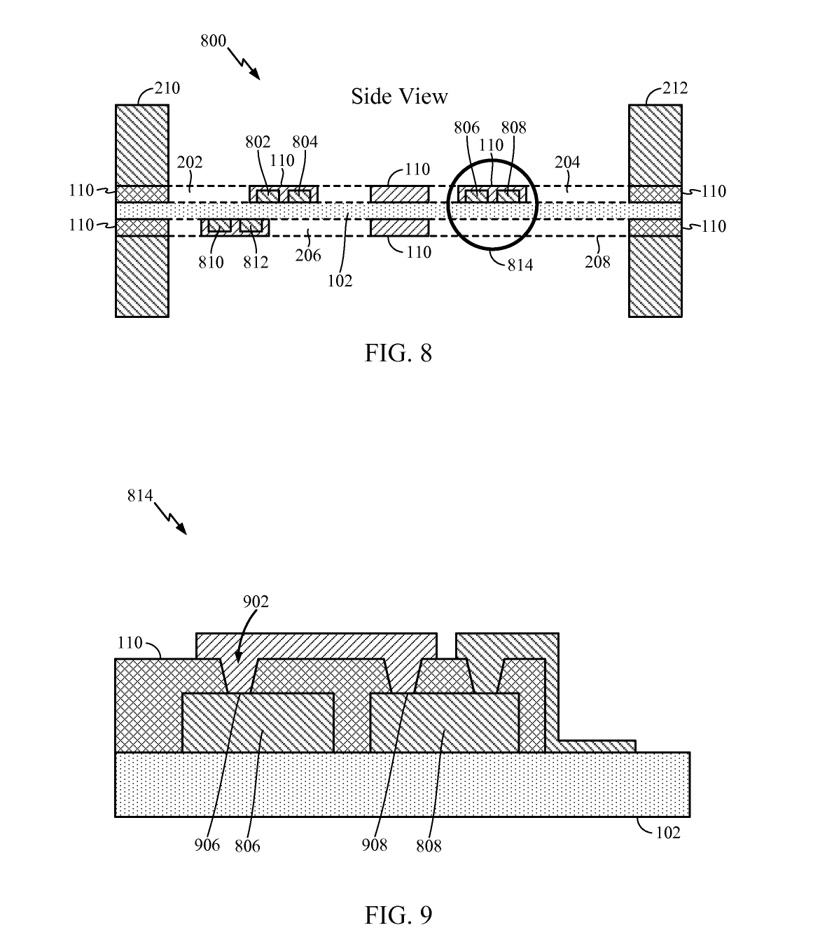

FIG. 8 is a side view of an integrated circuit package 800 according to implementations of the technology described herein. The integrated circuit package 800 is similar to the integrated circuit package 100 depicted in FIG. 2. For example, the integrated circuit package 800 includes the core 102 and the photo-patternable material 110 remaining on portions of the top and bottom sides of the surface of the core 102. The clamps 210 and 212 are disposed on the integrated circuit package 800 and are in contact with the remaining photo-patternable material 110. Dotted lines 202, 204, 206, and 208 represent portions of the photo-patternable material 110 which have been removed by patterning.

In addition to the integrated circuit package 100 depicted in FIG. 2, the implementation depicted in FIG. 8, includes the portions 202 and 204 on the top side and the portion 206 on the bottom side of the core 102. The portion 202 includes a component 802 and a component 804 formed on the surface of the core 102 on the top side. The portion 204 includes the components 806 and 808 formed on the surface of the core 102 on the top side. Similarly, components 810 and 812 formed on the surface of the core 102 on the bottom side. The photo-patternable material 110 is disposed on the components 802, 804, 806, 808, 810, and 812 and core 102 areas surrounding the components 802, 804, 806, 808, 810, and 812 such that the components 802, 804, 806, 808, 810, and 812 are embedded between the photo-patternable material 110 and the core 102.

In one or more implementations, the integrated circuit package 800 may be a System-in-Package (SiP), chip stack multi-chip module (MCM), or the like. For example, at least one component such as the components 802, 804, 806, 808, 810, and 812 may be disposed on the core 102. The at least one component may be a passive component, an active component, a silicon chip, a GaAs component, or a surface mount device formed using surface mount technology (SMT), or the like. The integrated circuit package 800 may be used for 2.5 dimension (2.5D) and three-dimension (3D) integration during fabrication of integrated circuit packages.

A region 814 having the components 806 and 808 is exploded in FIG. 9. In the illustrated implementation, the components 806 and 808 are disposed on the surface of the top side of the core 102. The photo-patternable material 110 is disposed on the components 806 and 808. The photo-patternable material 110 is also disposed on the core 102. The photo-patternable material 110 may be selectively removed from the sections such as 906 and 908 on the top surfaces of the components 806 and 808. A metal layer 902 is disposed on the photo-patternable material 110, the components 806 and 808, and the core 102, such that the metal layer 902 can make contact with the components 806 and 808 in the sections 906 and 908, respectively, where the photo-patternable material 110 was removed. The metal layer 902 may also be disposed in one or more through-core vias such as TGVs discussed in relation to FIGS. 6-7.

The metal layer 902 may be a copper redistribution layer (RDL) that makes electrical connections between the component 806 and 808. Although not shown in this view, one or more through-core vias may also be used in forming connections between components such as between any two or more of the components 802-812 on either side of the core 102.

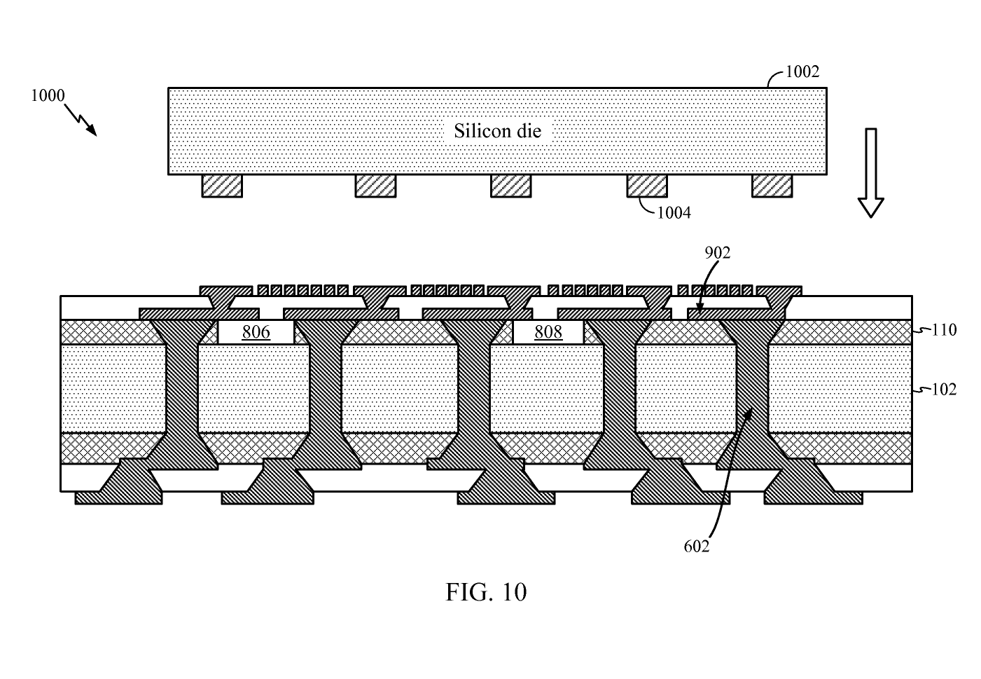

FIG. 10 is a side view of an integrated circuit package 1000 according to an implementation of the technology described herein. The integrated circuit package 1000 may be a multichip integrated circuit package comprising a silicon die 1002 attached or bonded to the metal layer 902 formed on the region 814, using the solder balls 1004 (which may be part of a ball grid array (BGA)), for example.

Components such as the components 806 and 808 formed on the surface of the top side of the core 102 are also shown. As previously, the photo-patternable material 110 is disposed on the components 806 and 808 and also on the core 102. Additionally, while the metal layer 902 is disposed on the photo-patternable material 110, the components 806, and the core 102, the metal layer 902 may also be formed or filled in one or more through-core vias such as TGV 602 discussed in relation to FIGS. 6-7.

The silicon die 1002 may be an application processor, a System-on-Chip (SoC) Mobile Station Modem (MSM) integrated circuit, or other suitable die.

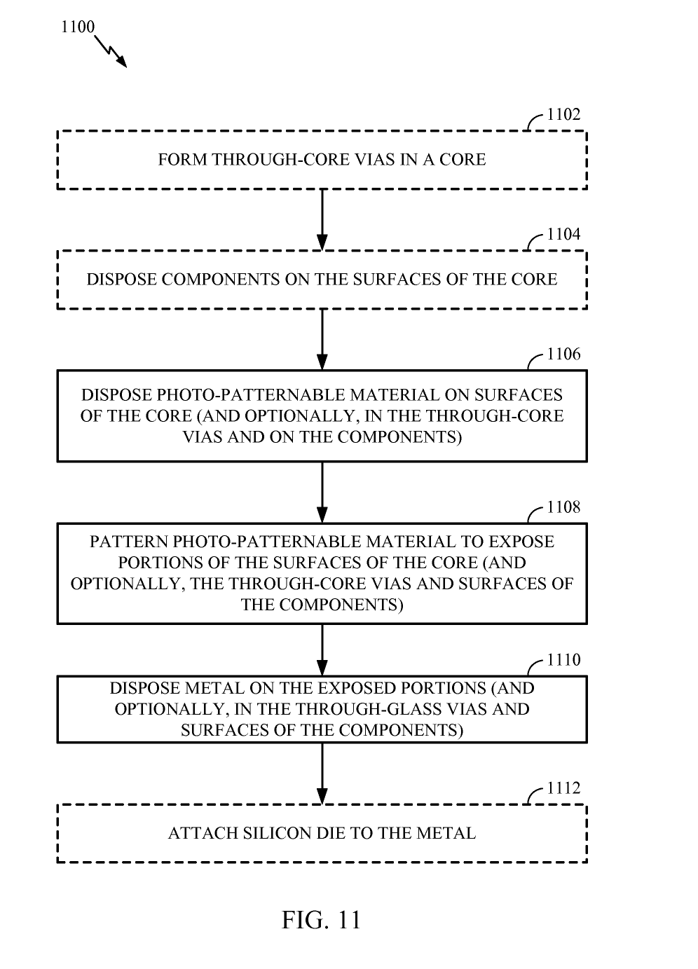

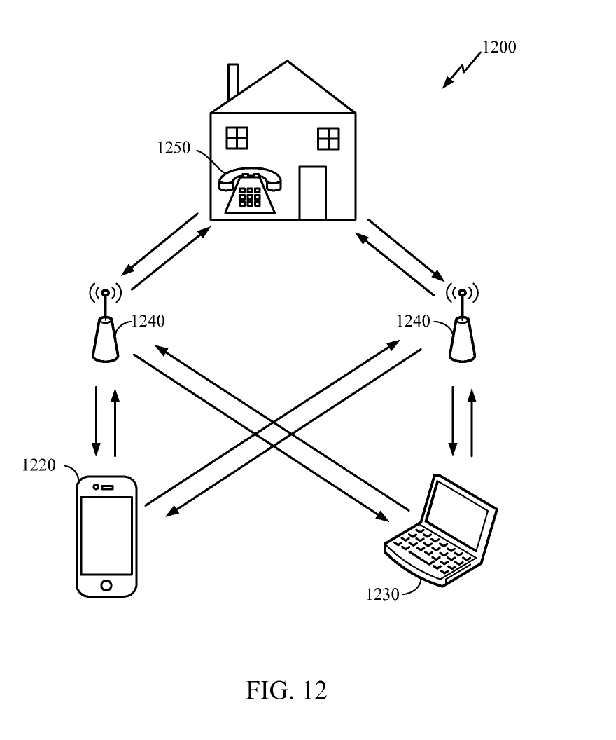

FIG. 11 is a flowchart of a method 1100 of fabricating a system such as the integrated circuit package 1000, according to an implementation of the technology described herein. Method 1100 is shown with two optional blocks 1102 and 1104 which may be part of some processes for forming the integrated circuit package 1000, but are not necessary. Similarly, block 1112 has also been shown to be optional and may be particular to some implementations, but is not necessary. Thus, it will be understood that method 1100 may start at block 1106 in some cases and finish at block 1110 in some cases. Moreover, some optional steps within blocks 1106-1110 are also shown within parenthesis to indicate steps which may be performed in conjunction with optional blocks 1102 and 1104 in particular cases.

As such, in the optional block 1102, one or more through-core vias (e.g. through-glass vias) may be formed in a core (e.g., a glass core). In one aspect, the core 102 may be a glass core and include two sides such as a first/top side and a second/bottom side and may be lapped to reduce surface roughness. The core 102 may be chemically etched to further smooth the surfaces of the top and bottom sides of the core 102. The surfaces of the top and bottom sides of the core 102 may be polished. The polished surfaces may undergo a final cleaning process to remove the polishing material. In one aspect, the core 102 may be laser drilled to form the TGV 602.

In the optional block 1104, one or more components may be disposed on the surfaces of the core. In one aspect, the components 802, 804, 806, 808, 810, and 812 are disposed correspondingly on the top and bottom sides of the surfaces of the core 102.

In a block 1106, a photo-patternable material is disposed on the core, and optionally disposed on the components (if any) and also filled into the through-core vias (if any). In one aspect, the photo-patternable material 110 is disposed on the top/bottom sides of the surfaces of the core 102, filling the TGV 602 (if TGVs were formed in the block 1102, for example), and on the components 802, 804, 806, 808, 810, and 812 (if components were disposed in the block 1104, for example), e.g., by spin coating or other suitable process.

In a block 1108, the photo-patternable material is patterned to expose portions of the surfaces of the core, and optionally, the through-core vias (if any) formed in the core. In one aspect, the method 1100 patterns the photo-patternable material 110 to expose the portions of the surfaces of the core 102 on the top/bottom sides. If TGVs were formed in the block 1102, the photo-patternable material 110 is also patterned to expose the TGV 602, for example. If the components were disposed on the surfaces of the core in the block 1104, then the photo-patternable material 110 is also patterned to expose sections 906 and 908 of the surfaces of the components 806 and 808, for example. A photo-mask may be used to define the areas of the photo-patternable material 110 that are to be removed/remain. Ultraviolet (UV) light or other suitable light source may be used to expose the photo-patternable material 110 according to the pattern provided by the photo-mask. Alternatively, mask-less lithography may be used to pattern the photo-patternable material 110.

In a block 1110, a metal is disposed on the exposed portions and optionally, within the exposed through-core vias (if any) and to make contact with the components (if any). In one aspect, the metal 702 may be disposed on the exposed portions of the surfaces of the core 102 and in the TGV 602 (if TGVs were formed in the block 1102, for example) using any suitable electroplating technique. In one aspect, metal layer 902 may make contact with the components 806 and 808 (if components were disposed in the block 1104, for example) through the sections 906 and 908 on the surfaces of the components 806 and 808 from which the photo-patternable material 110 was removed.

In the optional block 1112, a silicon die may be attached or bonded to the metal. In one or more implementations, the silicon die 1002 may be attached to the metal layer 902 using the solder balls 1004 (e.g., eutectic solder).

FIG. 12 illustrates an exemplary wireless communication system 1200 in which the core 102 or the integrated circuit package 1000 may be advantageously employed. For purposes of illustration, FIG. 12 shows three remote units 1220, 1230, and 1250 and two base stations 1240. In FIG. 12, remote unit 1220 is shown as a mobile telephone, remote unit 1230 is shown as a portable computer, and remote unit 1250 is shown as a fixed location remote unit in a wireless local loop system. For example, the remote units may be mobile phones, hand-held personal communication systems (PCS) units, portable data units such as personal data assistants, GPS enabled devices, navigation devices, settop boxes, music players, video players, entertainment units, fixed location data units such as meter reading equipment, or any other device that stores or retrieves data or computer instructions, or any combination thereof. Any of remote units 1220, 1230, and 1250 may include the integrated circuit package 1000 as disclosed herein.

Although FIG. 12 illustrates remote units according to the teachings of the disclosure, the disclosure is not limited to these exemplary illustrated units. Aspects of the disclosure may be suitably employed in any device which includes active integrated circuitry including memory and on-chip circuitry for test and characterization.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the aspects disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an aspect of the invention can include a computer readable media embodying a method of implementing a division or root computation with fast result formatting in the processor. Accordingly, the invention is not limited to illustrated examples and any means for performing the functionality described herein are included in aspects of the invention.

While the foregoing disclosure shows illustrative aspects of the invention, it should be noted that various changes and modifications could be made herein without departing from the scope of the invention as defined by the appended claims. The functions, steps and/or actions of the method claims in accordance with the aspects of the invention described herein need not be performed in any particular order. Furthermore, although elements of the invention may be described or claimed in the singular, the plural is contemplated unless limitation to the singular is explicitly stated.

1. An integrated circuit package, comprising:
a core comprising a surface on at least a first side;
a photo-patternable material disposed on the core except on at least an exposed portion of the surface of the core on the first side; and
a metal disposed on the exposed portion.

2. The integrated circuit package of claim 1, wherein the core comprises at least one through-core via exposed from the photo-patternable material and metal disposed in the exposed through-core via.

3. The integrated circuit package of claim 2, further comprising at least one component embedded between the photo-patternable material and the core.

4. The integrated circuit package of claim 3, wherein the at least one through-core via is coupled to the at least one component.

5. The integrated circuit package of claim 3, wherein the at least one component is a passive component, an active component, a silicon chip, a GaAs component, or a surface mount device (SMD).

6. The integrated circuit package of claim 2, further comprising:
a build-up film disposed on the at least one through-core via and the metal disposed on the exposed portion; and
a solder resist layer disposed on the build-up film.

7. The integrated circuit package of claim 1, wherein the photo-patternable material is at least one of a positive photoresist material, a negative photoresist material, a photo-patternable photo benzocyclobutene (BCB) material, a polyimide, or a polymer.

8. The integrated circuit package of claim 1, further comprising a silicon die attached to the metal.

9. The integrated circuit package of claim 1, wherein the core is a glass core.

10. A method for fabricating an integrated circuit package, the method comprising:
disposing a photo-patternable material on a surface of at least a first side of a core;
patterning the photo-patternable material to expose at least an exposed portion of the surface of at least the first side of the core; and
disposing a metal on the exposed portion.

11. The method of claim 10, further comprising forming at least one through-core via in the core, patterning the photo-patternable material to expose the at least one through-core via and disposing the metal in the exposed through-core via.

12. The method of claim 11, further comprising embedding at least one component between the photo-patternable material and the core.

13. The method of claim 12, further comprising coupling the at least one through-core via to the at least one component.

14. The method of claim 12, wherein the at least one component is a passive component, an active component, a silicon chip, a GaAs component, or a surface mount device (SMD).

15. The method of claim 11, further comprising:
disposing a build-up film on the at least one through-core via and the metal; and
disposing a solder resist layer on the build-up film.

16. The method of claim 10, comprising forming the photo-patternable material from least one of a positive photoresist material, a negative photoresist material, a photo-patternable photo benzocyclobutene (BCB) material, a polyimide, or a polymer.

17. The method of claim 10, further comprising attaching a silicon die attached to the metal.

18. The method of claim 10, comprising forming the core as a glass core.

19. An integrated circuit package, comprising:
a core comprising a surface on at least a first side;
photo-patternable means for improving mechanical handling of the core, disposed on the core except on at least an exposed portion of the surface of the core on the first side; and
means for making interconnections disposed on the exposed portion.

20. The integrated circuit package of claim 1, wherein the core comprises at least one means for connecting the first side and a second side of the core, and wherein the means for connecting is exposed from the photo-patternable material.
